(19) United States
(12) Patent Application Publication
(10) Pub. No.: US 2019/0003040 A1
(43) Pub. Date: Jan. 3, 2019

(54) APPLICATION OF MULTIPLE PLASMA COATING LAYERS IN A CONTINUOUS VACUUM

(71) Applicant: SABIC Global Technologies B.V., Bergen op Zoom (NL)

(72) Inventors: Huazhen YAO, Shanghai (CN); Hengjie LAI, Shanghai (CN); Chao LIU, Shanghai (CN); Yaming NIU, Shanghai (CN); Siguang JIANG, Shanghai (CN); Ashir THAKORE, Novi, MI (US)

(73) Assignee: Sabic Global Technologies B.V., Bergen op Zoom (NL)

(21) Appl. No.: 15/780,338

(22) PCT Filed: Nov. 28, 2016
(86) PCT No.: PCT/US2016/063819

§ 371 Date: May 31, 2018

Related U.S. Application Data
(60) Provisional application No. 62/262,191, filed on Dec. 2, 2015.

(51) Int. Cl. C23C 14/56; C23C 14/34; C23C 14/02; G02B 1/14; G02B 1/118

(52) U.S. Cl. CPC C23C 14/56; C23C 14/34; G02B 1/118; G02B 1/14; C23C 14/02

(57) ABSTRACT

A device and a process for applying multiple plasma coating layers in a vacuum, and a product created from that process. The process includes disposing a substrate in a vacuum chamber and applying multiple plasma coating layers to the substrate without breaking vacuum.

### TECHNICAL FIELD

The present disclosure generally relates to the application of layers to substrate surfaces.

### BACKGROUND

Polycarbonate is often used in forming an ophthalmic lens due at least to its anti-impact properties. But, polycarbonate may be susceptible to scratch/abrasion, which cause the polycarbonate lens to have a short lifecycle. Accordingly, there is a need to improve durability performance in polycarbonate lenses. As an example, conventional wet coating can be used to improve the lens anti-scratch performance, but wet coating is costly and has a bottle neck of the hardness. Furthermore, the formation of an ophthalmic lens may include the formation of functional layers. As a further example, light having a wavelength in the range of 380-500 nm is high energy visible light, which can be harmful to the human eye, especially the retina. However, much of the 380-500 nm wavelength range includes blue light (e.g., 400-480 nm). As such, it may be beneficial for lighting applications to emit light with the subject wavelength range of 380-500 nm. For example, light emitting diode (LED) lighting applications are being used in televisions, computer monitors, cellular devices, lightbulbs, and the like. LED lighting application can generate more blue light than conventional lighting applications or natural sunlight. Therefore, mechanisms for managing certain wavelengths of light are needed.

### SUMMARY

In various examples disclosed herein, methods and devices are disclosed for applying multiple plasma coating layers to a substrate in a continuous vacuum. In one example, An article may be formed via a process comprising: disposing a substrate inside a vacuum chamber; depositing a hard coat layer and depositing one or more layers onto the hard coating layer such as an anti-reflective (AR) layer or other functional layer, wherein each of the depositing the hard coat layer and the depositing the other layer is accomplished under vacuum pressure in series without breaking the vacuum.

In another example, a device may comprise: a vacuum chamber; a first target resource disposed in the vacuum chamber; a first plasma generator configured to cause a first plasma to interact with the first target resource to facilitate the deposition of a first layer on a film disposed in the vacuum chamber; a second target resource disposed in the vacuum chamber; and a second plasma generator configured to cause a second plasma to interact with the second target resource to facilitate the deposition of a second layer on the film disposed in the vacuum chamber, wherein the deposition of the first layer and the second layer are accomplished in a continuous manner.

In a further example, a method may comprise: pre-activating a surface of a substrate using a first plasma; generating a second plasma to cause a first target resource to be deposited on the pre-activated surface of the substrate as a first layer; and generating a third plasma to cause a second target resource to be deposited on the first layer.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to limitations that solve any or all disadvantages noted in any part of this disclosure.

### BRIEF DESCRIPTION OF THE DRAWINGS

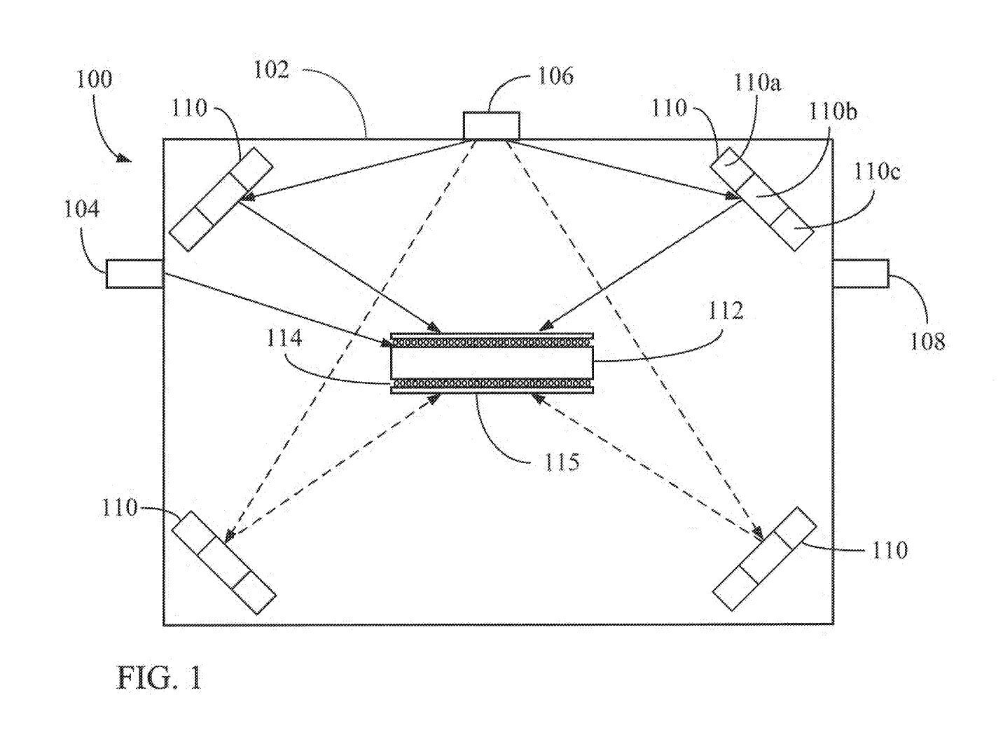

A more detailed understanding may be had from the following description, given by way of example in conjunction with the accompanying drawings wherein FIG. 1 illustrates a schematic of a film layer application device.

### DETAILED DESCRIPTION

In various examples disclosed herein, methods and devices are disclosed for applying multiple plasma coating layers to a substrate in a continuous vacuum. In one example, a substrate is disposed into a vacuum chamber. The atmospheric pressure in the vacuum chamber is lowered to a pressure that allows for the deposition of plasma coating layers on a substrate. A first plasma generator releases a pre-activate plasma that applies a pre-activate plasma layer to the surface of the substrate. A second plasma generator releases second plasma directed toward a target resources. The target resource is an ionic material, and the second plasma bombards the target resource, releasing particles of the target resource material into the vacuum. The particles bond with the pre-activate layer on the substrate, thus creating an activated first layer.

Without breaking vacuum, a second layer may be added using a third plasma generator. The third plasma generator may release a reagent plasma gas. The reagent plasma gas may react with a second target resource material. The reaction creates particles that will cause application of a second layer adjacent the first activated layer, thus creating two plasma coating layers on the substrate through one continuous process. In other words, the two layers were applied without breaking the vacuum.

The plasma coating layers applied to the substrate may be of various types. For example, the layers may include a scratch resistance layer, an anti-reflective (AR) layer, a blue ray blocking layer, or other layer (e.g., functional layer). The plasma coating layers may also be applied using different methods that use a Plasma enhanced Chemical vacuum deposition (PECVD), ion-beam sputtering, reactive sputtering, ion-assisted deposition, gas flow sputtering, etc. or a combination thereof. The process may be used to apply multiple player coating layers continuously to such products as ophthalmic lenses, windows, windshields, or other transparent optical products.

As described herein, FIG. 1 illustrates a schematic diagram of a multiple plasma layer application device 100 that may continuously apply multiple layers of film to a substrate. The layer application device 100 may include a vacuum chamber 102, a plurality of plasma generators 104, 106, 108, and one or more target resources 110. A substrate 112 may be disposed inside the vacuum chamber 102. The vacuum chamber 102 may be configured to provide a low pressure or vacuum environment therein. For example, the pressure inside the vacuum chamber 102 may be configured (e.g., reduced) to allow for the application of the film layers to the substrate 112 for the particular application method being used. For example, for sputtering, the pressure inside the vacuum chamber 102 may be between about 0.08 and about 0.02 mbar. Other pressures may be used, such as between about 1×10⁴ and about 10 Pa.

The plasma generators 104, 106, 108 may each be configured to emit the same or different plasma type. For example, the plasma generator 104 may generate plasma and may direct the plasma toward the substrate 112 to pre-activate a surface of substrate 112. The pre-activation may be accomplished prior to depositing a hard coating layer. As an example, pre-activating may include utilizing a gas (e.g., active or inactive) plasma to bombard the substrate 112 to thoroughly clean and make the surface of the substrate 112 active (e.g., ion energy to break the chemical bond or produce free radical) to improve the later chemical reaction and coating layer adhesion properties. As an example, the plasma generator 104 may produce an argon plasma or an oxygen plasma, however, other plasmas may be used. As another example, the plasma generator 106 may be a sputtering source, such as a sputtering gun. The plasma generator 106 may direct the plasma to at least one of target resources 110. The plasma generator 106 may emit argon plasma, nitrogen plasma, etc. The target resources 110 may be divided into sections 110a, 110b, and 110c. Each of sections 110a, 110b, and 110c may be a different material, such as graphite, silicone, tungsten, titanium, etc. The plasma generator 106 may be adjusted to direct plasma toward one of sections 110a, 110b, or 110c. The plasma emitted from the plasma generator 106 may react differently with each of the materials in sections 110a, 110b, and 110c. The plasma generator 106 may be pointed at the section 110a, 110b, or 110c composed of the desired material for a specific sputter deposition. The resulting particles from the sputter deposition may bond with the pre-active layer on substrate 112 to create activated layer 114.

Plasma generator 108 may produce a reagent plasma gas. One or more of sections 110a, 110b, and 110c of target resources 110 may be a material that reacts with the reagent plasma gas. The reaction may release particles that may result in the application of the coating layer 115 on the surface of substrate 112. It can be appreciated that the plasma coating layers created by plasma generators 104 and 106 and plasma generator 108 may be executed in any order.

In certain processes, the substrate 112 is placed in the vacuum chamber 102. The vacuum chamber 102 may be at normal atmospheric pressure when the substrate 112 is placed inside. In block 204 a vacuum is created in the vacuum chamber 102. The pressure in the vacuum chamber 102 may depend on the type of plasma coating film layer being applied to the substrate 112 and the method being used to apply the plasma coating film layer. For example, the pressure inside the vacuum chamber 102 may be between about 1×10⁴ and about 10 Pa.

The plasma generator 104 may generate a first plasma to pre-activate a surface of the substrate 112. Without breaking vacuum, the plasma generator 106 generates a second plasma. The second plasma may be directed to one of sections 110a, 110b, or 110c on target resources 110. The bombardment of the second plasma on the target resources 110 may cause the material on target resources 110 to erode, releasing particles into the vacuum chamber 102. The particles may bond with the pre-active layer, resulting in the activated layer 114 on the surface of the substrate 112. Without breaking vacuum, the third plasma generator 108 generates reagent plasma that produces a plasma gas that reacts with another material on target resources 110. The reaction releases particles that create a functional layer (e.g., coating layer 115) adjacent the activated layer 114. As an example, any plasma (e.g., gas, ion, reagent, etc.) may be used to cause application of any number of layers.

In an aspect, the substrate 112 is placed inside the vacuum chamber 102. The substrate 112 may be stationary inside the vacuum chamber 102 or it may be able to rotate. The pressure inside of vacuum chamber 102 may be lowered to a level necessary for the application of thin film layers on the substrate 112. For example, for the application of thin film layers via sputtering, the pressure inside the vacuum chamber 102 should typically be between 0.08 and 0.02 mbar. Plasma generator 104 may release a first plasma into the vacuum chamber 102. The first plasma may be argon, nitrogen, oxygen, hydrogen or other types of plasma. The first plasma may pre-activate the surface of the substrate 112.

Without breaking vacuum, the plasma generator 106 may apply a second plasma layer to the pre-activated layer via ion-assisted sputtering deposition. In this example, the plasma generator 106 may be a sputtering gun that directs the second plasma toward the target resources 110 inside of the vacuum chamber 102. The target resources 110 may include one or multiple materials. If the target resources 110 include multiple materials, such as sections 110a, 110b, and 110c, then plasma generator 106 may direct the second plasma at the section 110a, 110b, or 110c that has the desired material to create the desired film layer. For example, plasma generator 106 may direct the second plasma toward section 110a of target resources 110. Section 110a of target resources 110 may be graphite (for producing DLC). The collision of the second plasma with causes the graphite to be sputtered. The sputtered carbon plate may release particles that bond with the pre-activate layer and activate the pre-activated layer on the surface of the substrate 112. The activated layer 114 is thus created as a thin film DLC layer.

DLC may create a hard coated layer on the surface of plasma. This may serve to protect the substrate 112 from scratches, dents, and other types of damage. Other materials for target resources 110 that may create a hard coated layer are silicon dioxide, metal oxide, or polyurethane-base material, one or more of which can be deposited to the substrate together with DLC to improve the adhesion between the hard coating layer and the substrate 112. Target resources 110 may also be made of other material for creating other types of coating layers. For a blue ray blocking layer, target resources 110 may include silicone dioxide, zirconium dioxide, titanium dioxide, cobalt oxide, aluminum oxide, yttrium oxide, indium oxide, indium tin oxide, or any combination thereof.

The target resources 110 may comprise multiple materials. The multiple materials may be separated into sections 110a, 110b, and 110c. Each of sections 110a, 110b, and 110c may be of the same or different materials. If sections 110a, 110b, and 110c are all of different materials, then plasma generator 106 may be directed toward one of section 110a, 110b, or 110c to create the desired film layer on the surface of substrate 112. For example, section 110a may be graphite used for a hard coating layer, section 110b may be metal used for improving the adhesion of DLC layer to the substrate, and 110c may be silicone dioxide used for an AR (Anti-reflective) layer or blue ray blocking layer. To apply a hard coating layer, the plasma generator 106 may be directed at section 110a or 110b. To apply an AR (Anti-reflective) layer, the plasma generator 106 may be directed at section 110c. To apply a blue ray blocking layer, the plasma generator 106 may be directed at section 110c. The plasma generator 106 may produce different plasma for bombardment with each material, or a different plasma generator may be used for each material. Plasma generator 104 may generate a pre-active layer for each layer applied to the surface of substrate 112. This allows for multiple layers to be applied to the surface of substrate 112 continuously. For purposes of this disclosure, continuously may mean without breaking vacuum.

It can be appreciated that different types of plasma generators and film layer deposition may be used to apply film layers to the surface of substrate 112. For example, film layers may be added to the surface of substrate 112 via reactive sputtering, ion-beam deposition, gas flow sputtering, etc. Multiple coating layers may be continuously added to the surface of the substrate 112 using any combination of such methods.

In an aspect, a first layer (e.g., activated layer 114) may be applied to the surface of the substrate 112 via ion-assisted sputtering. The plasma generator 104 produces a first plasma that applies a pre-activate to the surface of substrate 112. The plasma generator 106 directs a second plasma to section 110a of the target resources 110 to bombard the material of section 110a, which is ionized. The resulting bombardment releases particles of the material of section 110a that bond with the pre-activate layer, and thus activates the pre-activate layer and creating the activated layer 114. Without breaking vacuum, the plasma generator 108 may then release gas plasma that serves as a reactant. The gas plasma reacts with a second material of section 110b of target resources 110. The resulting reaction creates a second layer (e.g., coating layer 115) on the surface of substrate 112. If desired, more layers may be added using the same of different application methods without breaking vacuum.

In another aspect, a first layer (e.g., activated layer 114) may be applied to the surface of the substrate 112 via ion-assisted sputtering. The plasma generator 104 produces a first plasma that applies a pre-activate to the surface of substrate 112. The plasma generator 106 directs a second plasma to section 110a of the target resources 110 to bombard the material of section 110a, which is ionized. The resulting bombardment releases particles of the material of section 110a that bond with the pre-activate layer, and thus activates the pre-activate layer and creating the activated layer 114. Without breaking vacuum, the plasma generator 104 may release another plasma that creates a second pre-activate layer on the surface of the first activated layer 114. The plasma generator 108 directs a third plasma to section 110b of the target resources 110 to bombard the material of section 110b. The material of section 110b may be ionized and a type of material that will create a different type of coating layer on the substrate 112 than the material of section 110a. The resulting bombardment releases particles of the material of section 110b that bond with the second pre-activate layer, and thus activates the pre-activate layer and creating the coating layer 115. If desired, more layers may be added using the same of different application methods without breaking vacuum.

In various aspects, the present disclosure pertains to and includes at least the following aspects.

Aspect 1: A device comprising: a vacuum chamber; a first target resource disposed in the vacuum chamber; a first plasma generator configured to cause plasma to pre-active the surface of the substrate disposed in the vacuum chamber; a second plasma generator configured to cause plasma to interact with the first target resource to facilitate the deposition of a first coating layer on the pre-activated substrate disposed in the vacuum chamber; a second target resource disposed in the vacuum chamber; and a third plasma generator configured to cause plasma to interact with the second target resource to facilitate the deposition of at least a second layer on the substrate disposed in the vacuum chamber, wherein the deposition of the first layer and the at least the second layer are accomplished in a continuous manner.

Aspect 2: A device comprising: a vacuum chamber; a first target resource disposed in the vacuum chamber; a first plasma generator configured to cause plasma to pre-active the surface of the substrate disposed in the vacuum chamber, wherein the first plasma generator is further configured to cause plasma to interact with the first target resource to facilitate the deposition of a first coating layer on the pre-activated substrate disposed in the vacuum chamber; a second target resource disposed in the vacuum chamber; and a second plasma generator configured to cause plasma to interact with the second target resource to facilitate the deposition of at least a second layer on the substrate disposed in the vacuum chamber, wherein the deposition of the first layer and the at least the second layer are accomplished in a continuous manner.

Aspect 3: The device of any of aspects 1-2, wherein the substrate comprises an optical lens or optical film.

Aspect 4: The device of any of aspects 1-2, wherein the substrate comprises polycarbonate, polycarbonate co-polymer, CR39, PMMA or other similar existing material capable of being formed into an optical article.

Aspect 5: The device of any of aspects 1-4, wherein the plasmas comprise an active gas plasma, an inactive gas plasma, reagent plasma, or sputtered ions.

Aspect 6: The device of any of aspects 1-5, wherein one or more of the first target resource and the second target resource comprises graphite, a silicone-base, polyurethane, or a metal.

Aspect 7: The device of any of aspects 1-6, wherein one or more of the first layer and the second layers comprises one or more of an anti-reflective layer and a blue ray cutting layer.

Aspect 8: An article comprising the substrate, the first layer, and the second layer formed using the device of any of aspects 1-7.

Aspect 9: The article of aspect 8, wherein the article exhibits a pencil hardness of greater than 1H using pencil hardness test ASTM D3363.

Aspect 10: The article of any of aspects 8-9, wherein the article exhibits a Bayer value of greater than 1 using the Bayer test.

Aspect 11: The article of any of aspects 8-10, wherein one or more of the first layer and the second layer has a thickness of from about 0.1 micron to about 50 microns.

Aspect 12: The article of any of aspects 8-11, wherein the substrate has a thickness of from about 0.5 mm to about 20 mm.

Aspect 13: A method comprising: pre-activating a surface of a lens substrate using a first plasma, wherein the substrate is disposed in a vacuum chamber; and generating a second plasma to cause a first target resource to be deposited on the pre-activated surface of the substrate as a first layer, without breaking the vacuum.

Aspect 14: The method of aspect 13, further comprising generating a third plasma to cause at least a second target resource to be deposited on one or more of the substrate and the first layer.

Aspect 15: The method of any of aspects 13-14, wherein the substrate comprises an optical lens or optical film.

Aspect 16: The method of any of aspects 13-15, wherein the substrate comprises polycarbonate, polycarbonate co-polymer, CR39, PMMA or other similar existing material capable of being formed into an optical article.

Aspect 17: The method of any of aspects 13-16, wherein one or more of the first plasma and the second plasma comprises an active gas plasma, an inactive gas plasma, reagent plasma, or sputtered ions.

Aspect 18: The method of any of aspects 13-17, wherein the first target resource comprises graphite, a silicone-base, polyurethane, or a metal.

Aspect 19: The method of any of aspects 13-18, wherein the first layer comprises one or more of an anti-reflective layer and a blue ray cutting layer.

Aspect 20: An article formed using the method of any of aspects 13-19.

Aspect 21: An article formed via a process comprising: disposing a substrate inside a vacuum chamber; depositing an anti-scratch layer adjacent the substrate; and depositing a functional layer adjacent one or more of the substrate and the anti-scratch layer; wherein each of the depositing the anti-scratch layer and the depositing the functional layer is accomplished under vacuum pressure in series without breaking the vacuum.

Aspect 22: The article of aspect 21, wherein the substrate forms at least a portion of an ophthalmic lens.

Aspect 23: The article of any of aspects 21-22, wherein the depositing the anti-scratch layer comprises: pre-activating a surface of the substrate using a first plasma; and generating a second plasma to cause a first target resource to be deposited on the pre-activated surface of the substrate as the anti-scratch layer.

Aspect 24: The article of any of aspects 21-23, wherein one or more of the first plasma and the second plasma comprises an active gas plasma, an inactive gas plasma, reagent plasma, or sputtered ions.

Aspect 25: The article of any of aspects 21-24, wherein the first target resource comprises graphite, a silicone-base, polyurethane, or a metal.

Aspect 26: The article of any of aspects 21-25, wherein the functional layer comprises one or more of an anti-reflective layer and a blue ray cutting layer.

Aspect 27: The article of any of aspects 21-26, wherein the functional layer is deposited onto the anti-scratch layer.

Aspect 28: The article of any of aspects 21-27, wherein the article exhibits a pencil hardness of greater than 1H using pencil hardness test ASTM D3363.

Aspect 29: The article of any of aspects 21-28, wherein the article exhibits a Bayer value of greater than 1 using the Bayer test.

Aspect 30: The article of any of aspects 21-29, wherein the anti-scratch layer has a thickness of from about 0.1 micron to about 50 microns.

Aspect 31: The article of any of aspects 21-30, wherein the substrate comprises polycarbonate, polycarbonate co-polymer, CR39, PMMA or other similar existing material capable of being formed into an optical article.

Aspect 32: The article of any of aspects 21-31, wherein the substrate has a thickness of from about 0.5 mm to about 20 mm.

Aspect 33: The article of any of aspects 21-32, wherein the substrate comprises a transparent article or a translucent article.

Aspect 34: An article formed via a process comprising: disposing a substrate inside a vacuum chamber; depositing a hard coating layer adjacent the substrate; and depositing a functional layer adjacent one or more of the substrate and the hard coating layer; wherein each of the depositing the hard coating layer and the depositing the functional layer is accomplished under vacuum pressure in series without breaking the vacuum.

Aspect 35: The article of aspect 34, wherein the substrate forms at least a portion of an ophthalmic lens.

Aspect 36: The article of any of aspects 34-35, wherein the depositing the hard coating layer comprises: pre-activating a surface of the substrate using a first plasma; and generating a second plasma to cause a first target resource to be deposited on the pre-activated surface of the substrate as the hard coating layer.

Aspect 37: The article of aspect 36, wherein one or more of the first plasma and the second plasma comprises an active gas plasma, an inactive gas plasma, reagent plasma, or sputtered ions.

Aspect 38: The article of any of aspects 34-37, wherein the first target resource comprises graphite, a silicone-base, polyurethane, or a metal.

Aspect 39: The article of any of aspects 34-38, wherein the functional layer comprises one or more of an anti-reflective layer and a blue ray cutting layer.

Aspect 40: The article of any of aspects 34-39, wherein the functional layer is deposited onto the hard coating layer.

Aspect 41: An article formed via a process comprising: disposing a photochromic substrate inside a vacuum chamber; depositing an anti-scratch layer adjacent the substrate; and depositing a functional layer adjacent one or more of the substrate and the anti-scratch layer; wherein each of the depositing the anti-scratch layer and the depositing the functional layer is accomplished under vacuum pressure in series without breaking the vacuum.

Aspect 42: The article of aspect 41, wherein the substrate forms at least a portion of an ophthalmic lens.

Aspect 43: The article of any of aspects 41-42, wherein the depositing the anti-scratch layer comprises: pre-activating a surface of the substrate using a first plasma; and generating a second plasma to cause a first target resource to be deposited on the pre-activated surface of the substrate as the anti-scratch layer.

Aspect 44: The article of any of aspects 41-43, wherein one or more of the first plasma and the second plasma comprises an active gas plasma, an inactive gas plasma, reagent plasma, or sputtered ions.

Aspect 45: The article of any of aspects 41-44, wherein the first target resource comprises graphite, a silicone-base, polyurethane, or a metal.

Aspect 46: The article of any of aspects 41-45, wherein the functional layer comprises one or more of an anti-reflective layer and a blue ray cutting layer.

Aspect 47: The article of any of aspects 41-46, wherein the functional layer is deposited onto the anti-scratch layer.

Aspect 48: The article of any of aspects 41-47, wherein the article exhibits a pencil hardness of greater than 1H using pencil hardness test ASTM D3363.

Aspect 49: The article of any of aspects 41-48, wherein the article exhibits a Bayer value of greater than 1 using the Bayer test.

Aspect 50: The article of any of aspects 41-49, wherein the anti-scratch layer has a thickness of from about 0.1 micron to about 50 microns.

Aspect 51: The article of any of aspects 41-50, wherein the substrate comprises polycarbonate, polycarbonate co-polymer, CR39, PMMA or other similar existing material capable of being formed into an optical article.

Aspect 52: The article of any of aspects 41-51, wherein the substrate has a thickness of from about 0.5 mm to about 20 mm.

Aspect 53: The article of any of aspects 41-52, wherein the substrate comprises a transparent article or a translucent article.

Aspect 54: An article formed via a process comprising: disposing a photochromic substrate inside a vacuum chamber; depositing a hard coating layer adjacent the substrate; and depositing a functional layer adjacent one or more of the substrate and the hard coating layer; wherein each of the depositing the hard coating layer and the depositing the functional layer is accomplished under vacuum pressure in series without breaking the vacuum.

Aspect 55: The article of aspect 54, wherein the substrate forms at least a portion of an ophthalmic lens.

Aspect 56: The article of any of aspects 54-55, wherein the depositing the hard coating layer comprises: pre-activating a surface of the substrate using a first plasma; and generating a second plasma to cause a first target resource to be deposited on the pre-activated surface of the substrate as the hard coating layer.

Aspect 57: The article of aspect 56, wherein one or more of the first plasma and the second plasma comprises an active gas plasma, an inactive gas plasma, reagent plasma, or sputtered ions.

Aspect 58: The article of any of aspects 54-57, wherein the first target resource comprises graphite, a silicone-base, polyurethane, or a metal.

Aspect 59: The article of any of aspects 54-58, wherein the functional layer comprises one or more of an anti-reflective layer and a blue ray cutting layer.

Aspect 60: The article of any of aspects 54-59, wherein the functional layer is deposited onto the hard coating layer.

### INDUSTRIAL APPLICABILITY

Polycarbonate is becoming more and more popular for ophthalmic lenses due to its anti-impact properties. But polycarbonate is very susceptible to scratches and abrasions which significantly shortens the life of the lens. A low cost coating system is needed which also can increase the scratch resistance of the lens. For blue ray blocking, the conventional methods are coating the inorganic metal oxide or organic pigment and incorporating yellow dye in the matrix. The coating technology is very costly and the incorporating yellow dye in the matrix produces a yellowish color in the lens, which may not be cosmetically appealing to the customer. The coating technology is very complex, costly and is not very durable. The imbibition and in-matrix are not workable for the rigid matrix (such as polycarbonate), which does not have enough free volume for the color switching in the matrix.

As described herein, plasma technology may be used for organic or inorganic coating on the surface of an optical matrix to reduce the system cost and improve the durability of coating and substrate. The systems and methods of the present disclosure provide combined, continuous technology of plasma pre-activate, ion assisted sputtering, and plasma assisted deposition technology to build a continuous plasma coating process to improve the lens durability. In order to add two or more layers to a substrate surface for AR (anti-reflective) film, blue ray blocking, or many other types of layers, a vacuum may be created for each layer. Conventionally, the vacuum is broken and recreated for each layer that must be applied. Often the substrate must be transferred to an entirely different machine to add an additional layer. Therefore, as described herein, there is a need for an efficient system and method to apply multiple layers to a substrate where the application of the layers requires a vacuum.

In an aspect, the disclosure relates to a combination of plasma technology (e.g., plasma pre-activating, plasma sputtering ion, plasma deposition, gas carried precursor reagent) in a continuous process. Such a process may form an anti-scratch/abrasion layer on the substrate surface to improve the lens durability performance and reduce the coating process procedures and even the scrape rate. The plasma formed coating layer can improve the lens pencil hardness from the general 2B to 3H or greater, and/or a Bayer value from about 1 to 4 or greater, without narratively impacting the optical properties. Although a polycarbonate substrate is discussed herein, the disclosed plasma coating technology can be utilized on many lens materials, such as are PU/CR-39/Trivex/PMMA, and other similar transparent articles.

In another aspect, the lens article properties were tested and are provided in Table 1 (below):

TABLE 1

| Item | Value | Test method/Regulatory |
|---|---|---|
| Impact/Ball drop test | | ANSI Z80.1, QB 2506-2001 |
| Chemical resistance | pass | Clean agent, cola, alcohol, salt fog, |
| | | refer to ANSI Z16.1 test method |
| Bayer Value | 1+ | Bayer test, ASTM F735 (4+) |
| Regulatory compliance | | GB10810, EN89803, ANSI Z80.1 |
| Blue ray cutting level | | 380-500 nm with >50% blue ray |
| | | blocking |

The disclosed subject matter associated with applying multiple plasma coating layers in a vacuum has been described with reference to several examples. It should be understood, however, that the words used are for descriptive and illustrative purposes, rather than as mere limitations. Although the methods and device for applying multiple plasma coating layers in a vacuum has been described in terms of particular means, processes, materials, technologies, and the like, the disclosed subject matter extends to functionally equivalent technologies, structures, methods, and uses that are within the scope of the claims.

What is claimed:

1. A device comprising:
a vacuum chamber;
a first target resource disposed in the vacuum chamber;
a first plasma generator configured to cause plasma to pre-active the surface of the substrate disposed in the vacuum chamber;
a second plasma generator configured to cause plasma to interact with the first target resource to facilitate the deposition of a first coating layer on the pre-activated substrate disposed in the vacuum chamber;
a second target resource disposed in the vacuum chamber; and
a third plasma generator configured to cause plasma to interact with the second target resource to facilitate the deposition of at least a second layer on the substrate disposed in the vacuum chamber,
wherein the deposition of the first layer and the at least the second layer are accomplished in a continuous manner.

2. (canceled)

3. The device of claim 1, wherein the substrate comprises an optical lens or optical film.

4. The device of claim 1, wherein the substrate comprises polycarbonate, polycarbonate co-polymer, CR39, PMMA or other similar existing material capable of being formed into an optical article.

5. The device of claim 1, wherein the plasmas comprise an active gas plasma, an inactive gas plasma, reagent plasma, or sputtered ions.

6. The device of claim 1, wherein one or more of the first target resource and the second target resource comprises graphite, a silicone-base, polyurethane, or a metal.

7. The device of claim 1, wherein one or more of the first layer and the second layers comprises one or more of an anti-reflective layer and a blue ray cutting layer.

8. An article comprising the substrate, the first layer, and the second layer formed using the device of claim 1.

9. The article of claim 8, wherein the article exhibits a pencil hardness of greater than 1H using pencil hardness test ASTM D3363.

10. The article of claim 8, wherein the article exhibits a Bayer value of greater than 1 using the Bayer test.

11. The article of claim 8, wherein one or more of the first layer and the second layer has a thickness of from about 0.1 micron to about 50 microns.

12. The article of claim 8, wherein the substrate has a thickness of from about 0.5 mm to about 20 mm.

13. A method comprising:
pre-activating a surface of a lens substrate using a first plasma, wherein the substrate is disposed in a vacuum chamber; and
generating a second plasma to cause a first target resource to be deposited on the pre-activated surface of the substrate as a first layer, without breaking the vacuum.

14. The method of claim 13, further comprising generating a third plasma to cause at least a second target resource to be deposited on one or more of the substrate and the first layer.

15. The method of claim 13, wherein the substrate comprises an optical lens or optical film.

16. The method of claim 13, wherein the substrate comprises polycarbonate, polycarbonate co-polymer, CR39, PMMA or other similar existing material capable of being formed into an optical article.

17. The method of claim 13, wherein one or more of the first plasma and the second plasma comprises an active gas plasma, an inactive gas plasma, reagent plasma, or sputtered ions.

18. The method of claim 13, wherein the first target resource comprises graphite, a silicone-base, polyurethane, or a metal.

19. The method of claim 13, wherein the first layer comprises one or more of an anti-reflective layer and a blue ray cutting layer.

20. An article formed using the method of claim 13.
